(19) United States
(12) Patent Application Publication
(10) Pub. No.: US 2020/0045831 A1
(43) Pub. Date: Feb. 6, 2020

(54) METHOD OF FORMING MATERIAL FOR A CIRCUIT USING NICKEL AND PHOSPHOROUS

(71) Applicant: HUTCHINSON TECHNOLOGY INCORPORATED, Hutchinson, MN (US)

(72) Inventors: Paul V. Pesavento, Hutchinson, MN (US); Douglas P. Riemer, Waconia, MN (US); Michael E. Roen, Hutchinson, MN (US)

(21) Appl. No.: 16/529,614

(22) Filed: Aug. 1, 2019

Related U.S. Application Data
(60) Provisional application No. 62/714,594, filed on Aug. 3, 2018.

(51) Int. Cl. H05K 3/18; H05K 1/09; C23C 18/18; C23C 18/34

(52) U.S. Cl. CPC H05K 3/181; H05K 1/09; H05K 1/0277; C23C 18/34; H05K 2203/072; C23C 18/1893

(57) ABSTRACT

A method of plating a conductive material includes providing conductive material. An aqueous bath solution comprised of at least one solvent, a nickel source, a phosphorous source, a reducing agent, a pH-controlling material, a stabilizer and a complexing agent is used to plate the conductive material. The conductive material contacts the bath solution. Electroless plating occurs on top of the conductive material and the plating includes from about 88 to 93 wt. % nickel and from at least 7 to about 12 wt. % phosphorous to form a nickel-phosphorous plating. The thickness of the plating is from about 50 to about 300 nm and the plating is generally uniform with the thickness of the surface being within 20 percent of the average thickness across the surface of the plating.

### RELATED APPLICATIONS

This application claims the benefit of, and priority to, U.S. Provisional Patent Application Ser. No. 62/714,594 filed on Aug. 3, 2018, titled Method of Forming Material for a Circuit Using Nickel and Phosphorous, the entire disclosure of which is hereby incorporated by reference.

### TECHNICAL FIELD

Embodiments of the present invention relates to a method of forming material for a circuit. More specifically, the method includes using nickel and a high phosphorous content material for forming a circuit such as a flexible circuit.

### BACKGROUND

Circuits, such as flexible circuits, typically include conductive and insulating layers. Flexible circuits may be used to form a variety of electronic components or devices. In one example, flexible circuits such as flexures used in disk drives are structures that flexibly support a read/write transducer proximate a rotating disk, while also supporting flexible electrical circuitry for conducting electrical signals to and from a transducer. The material typically includes a substrate, a dielectric polymer layer and conductive material. One method of forming such a material includes electroless plating on top of the conductive material.

One problem that can occur in the resultant conductive material used in electrical circuitry that has been electroless plated is unacceptably high order-to-order bandwidth variation. Thus, it would be desirable to have a method of forming material for a circuit (e.g., flexible circuit) that does not have unacceptably high order-to-order bandwidth variation and is done in a simple, efficient and cost-effective manner without causing other unintended problems.

### SUMMARY

According to one method, a circuit is formed that includes forming a substrate, forming a dielectric polymer layer and forming a seed layer in which the dielectric polymer layer is located between the substrate and the seed layer. Conductive material is placed on a first portion of the seed layer. The conductive material contacts with or in an aqueous bath solution. Electroless plating occurs on top of the conductive material. The electroless plating includes an aqueous bath solution comprising at least one solvent, a nickel source, a phosphorous source, a reducing agent, a pH-controlling material, a stabilizer and a complexing agent. The plating includes from about 88 to 93 wt. % nickel and from at least 7 to about 12 wt. % phosphorous to form a nickel-phosphorous plating or layer on the conductive material. The thickness of the nickel-phosphorous plating or layer is from about 50 to about 300 nm. The nickel-phosphorous plating or layer is generally uniform with the thickness of the surface being within 20 percent of the average thickness across the surface of the plating.

According to another method, a circuit is formed that includes forming a substrate, forming a dielectric polymer layer and forming a seed layer in which the dielectric polymer layer is located between the substrate and the seed layer. Conductive material is placed on a first portion of the seed layer. The conductive material is copper or a copper alloy. The conductive material is contacted with or in an aqueous bath solution. Electroless plating occurs on top of the conductive material. The electroless plating includes an aqueous bath solution consisting essentially of at least one solvent, a nickel source, a phosphorous source, a reducing agent, a pH-controlling material, a stabilizer and a complexing agent. In some embodiments, the reducing agent is sodium hypophosphite or hypophosphorous acid. The pH-controlling material is sodium hydroxide or potassium hydroxide. The complexing agent is succinic acid, maleic acid, lactic acid, gluconic acid or a Krebs-cycle acid. The plating includes from about 88 to about 92 wt. % nickel and from about 8 to about 12 wt. % phosphorous to form a nickel-phosphorous plating on the conductive material. The thickness of the nickel-phosphorous plating is from about 100 to about 300 nm. The nickel-phosphorous plating is generally uniform with the thickness of the surface is within 20 percent of the average thickness across the surface of the plating.

According to a further method, a conductive material is provided. An aqueous bath solution is provided that consists essentially of at least one solvent, a nickel source, a phosphorous source, a reducing agent, a pH-controlling material, a stabilizer and a complexing agent. The conductive material contacts with or in the aqueous bath solution. Electroless plating occurs on top of the conductive material. The plating includes from about 88 to 93 wt. % nickel and from at least 7 to about 12 wt. % phosphorous to form a nickel-phosphorous plating on the conductive material. The thickness of the nickel-phosphorous plating is from about 50 to about 300 nm. The nickel-phosphorous plating is generally uniform with the thickness of the surface being within 20 percent of the average thickness across the surface of the plating.

### BRIEF DESCRIPTION OF THE DRAWINGS

The accompanying drawings, which are incorporated in and constitute a part of this specification, exemplify various embodiments, and together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a generally cross-sectional view of a portion of a flexible circuit with at least one opening in a dielectric polymer layer according to one embodiment.

FIG. 2 is a generally cross-sectional view of the portion of the flexible circuit shown in FIG. 1 after deposition of a seed layer according to one embodiment.

FIG. 3 is a generally cross-sectional view of the portion of the flexible circuit shown in FIG. 2 after forming a patterned photoresist layer according to one embodiment.

FIG. 4 is a generally cross-sectional view of the portion of the flexible circuit shown in FIG. 3 after forming conductive structures onto portions of the seed layer according to one embodiment.

FIG. 5 is a generally cross-sectional view of the portion of the flexible circuit shown in FIG. 4 after electroless plating nickel and phosphorous on top of the conductive material according to one embodiment.

FIG. 6 is a 3-dimensional depiction of bandwidth loss as a function on electroless nickel-phosphorous using percentages of phosphorous and thickness.

### DETAILED DESCRIPTION

Embodiments described below are directed to methods of forming material to be used in forming, for example, circuits. One non-limiting example of a circuit is a flexible circuit. In some embodiments, the flexible circuits are flexures of a hard disk drive suspension, such as a suspension described in U.S. Pat. Nos. 9,296,188 or 8,891,206, both of which are hereby incorporated by reference in their respective entireties.

Embodiments of the present invention in one method is directed to forming material for a circuit such as a flexible circuit. The method comprises forming a substrate, forming a dielectric polymer layer and forming a seed layer in which the dielectric polymer layer is located between the substrate and the seed layer. The conductive material is placed on a first portion of the seed layer. The conductive material contacts with or in the aqueous bath solution. Electroless plating is performed on top of the conductive material. The electroless plating includes an aqueous bath solution consisting essentially of at least one solvent, a nickel source, a phosphorous source, a reducing agent, a pH-controlling material, a stabilizer and a complexing agent. The plating includes from about 88 to 93 wt. % nickel and from at least 7 to about 12 wt. % phosphorous to form a nickel-phosphorous plating on the conductive material. The thickness of the nickel-phosphorous plating is from about 50 to about 300 nm. The nickel-phosphorous plating is generally uniform with the thickness of the surface being within 20 percent of the average thickness across the surface of the plating.

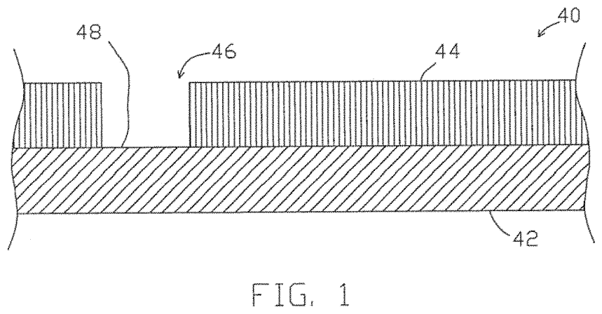

Referring to FIG. 1, a generally cross-sectional view of a portion of a flexible circuit with at least one opening in a dielectric polymer layer according to one embodiment. It is contemplated that a flexible circuit may not include any openings in the dielectric polymer layer or may include a plurality of openings in the dielectric polymer layer. The flexible circuit may be a flexure in one embodiment.

FIG. 1 shows a flexible circuit 40 including a substrate 42, a dielectric polymer layer 44, and an opening 46. The substrate 42 may be a flexible metal substrate or other conductive material. The substrate 42 desirably includes stainless steel. In other embodiments, the substrate 42 may include metallic materials such as copper, phosphorus bronze, nickel, titanium or alloys thereof such as, for example, nitinol. The metal does not have to be continuous in the substrate, but the metal is used in at least the areas where a circuit is desired.

The dielectric polymer layer 44 may comprise a suitable, curable polymer. One non-limiting example that may be used to form the dielectric polymer layer 44 is polyimide. The dielectric polymer layer 44 is disposed on a surface 48 of the substrate 42. The opening 46 is an opening in the dielectric polymer layer 44 that extends through the dielectric polymer layer 44 to expose a portion of the surface 48. The opening 46 may be used to establish an electrical connection between a conductive material (e.g., a conductive structure) formed on the dielectric polymer layer 44 and the substrate 42.

In some embodiments, the dielectric polymer layer 44 may be formed by depositing a photoimageable polyimide precursor onto the surface 48, followed by photolithographic processes well known in the art, including exposing the polyimide precursor through a photomask and developing to form the opening 46. Once the opening 46 is formed, the polyimide precursor is cured to form the polyimide.

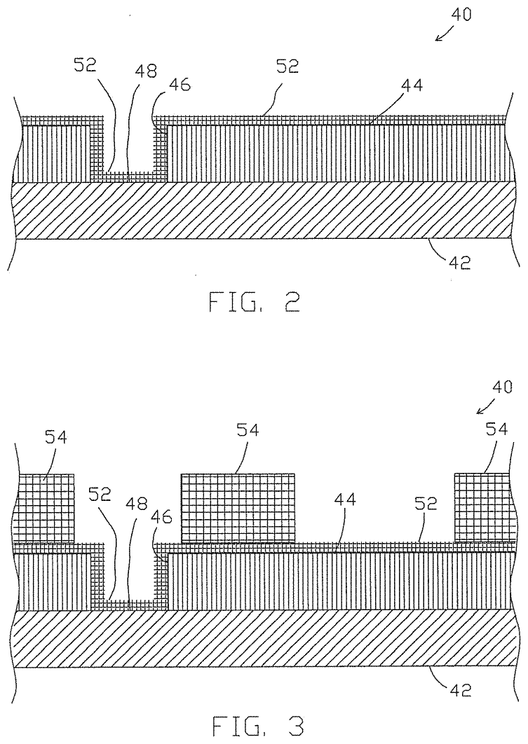

FIG. 2 is a generally cross-sectional view of the portion of the flexible circuit 40 showing additional processing according to one embodiment after the processing described above in reference to FIG. 1. FIG. 2 shows a seed layer 52 deposited onto the dielectric polymer layer 44 and the exposed portion of the surface 48 of the substrate 42. The seed layer 52 assists in adhering the dielectric layer 44 and a conductive layer or structure as will be discussed below. The seed layer 52 forms a low resistance electrical connection with the substrate 42. The seed layer 52 may be formed, for example, by sputter deposition of a metallic layer (e.g., a chromium layer) onto the dielectric layer 44 and the exposed portion of the surface 48 of the substrate 42.

The thickness of the seed layer 52 is generally from about 200 to about 1,250 A and, more specifically, from about 300 to about 600 A. It is contemplated that the seed layer may include more than one layer. For example, the seed layer may include a thin chromium layer and a thin copper layer.

FIG. 3 is a generally cross-sectional view of the portion of the flexible circuit 40 showing additional processing according to one embodiment after the processing described above in FIG. 2. FIG. 3 shows a patterned photoresist layer 54 formed on the seed layer 52. The patterned photoresist layer 54 can be formed by photolithographic techniques well known in the art.

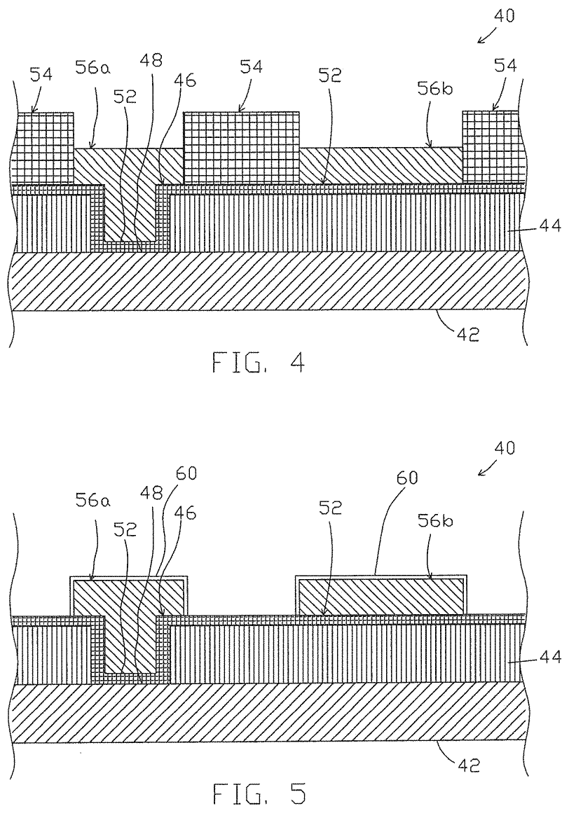

FIG. 4 is a generally cross-sectional view of the portion of the flexible circuit 40 showing additional processing according to one embodiment after the processing described above in FIG. 3. FIG. 4 shows the formation of conductive material such as, for example, conductive structures 56a, 56b on the seed layer 52. The plurality of conductive structures 56a, 56b are formed onto portions of the seed layer 52 not covered by the patterned photoresist layer 54. The conductive structures 56a, 56b in one embodiment may be copper or a copper alloy. It is contemplated that the conductive material may include materials such as cobalt, zinc, nickel, iron, gold, silver and alloys thereof.

The patterned photoresist layer 54 blocks deposition of the conductive metal onto the seed layer 52. While just two conductive structures, 56a and 56b, are shown for ease of illustration, it is understood that embodiments may include more than two conductive structures.

In one method, after the conductive structures 56a, 56b are formed, the photoresist layer 54 is stripped. The conductive material (e.g., conductive structures 56a, 56b) to be plated is typically cleaned by a series of chemicals, which is generally known as the pre-treatment process. This is performed before electroless plating in this method. The pre-treatment process assists in removing unwanted material from the surface to be plated, which assists in performing a better plating. The series of chemical treatments also includes water-rinsing steps to remove any chemicals that may adhere to the surface of the conductive material. The pre-treatment process may also include an activation step.

It is contemplated that the substrate, dielectric polymer layer, seed layer and conductive material may be formed by different methods other than those specifically described above with respect to FIGS. 1-4.

After the conductive material is formed and potentially pre-treated, it is then electroless plated. The electroless plating includes an aqueous bath solution comprising or consisting essentially of at least one solvent, a nickel source, a phosphorous source, a reducing agent, a pH-controlling material, a stabilizer and a complexing agent.

The electroless plating using the aqueous bath solution protects the conductive material from corrosion. If copper and a polyimide layer are used, the electroless plating also acts as a diffusion barrier. It is desirable for the electroless plating from the aqueous bath solution to exhibit no bandwidth degradation. Electrical performance is a very important consideration because it directly affects functional performance of the circuit (e.g., a flexure) and is important for stacked and interleaved designs. It is also desirable for the electroless plating to not negatively affect any of its mechanical performance.

The aqueous bath solution includes at least one solvent. The solvent typically used in the aqueous bath solution is water, however other solvents may be used in the aqueous bath solution.

The nickel source to be used in the aqueous bath solution is desirably highly soluble in the selected solvent. In one embodiment, the nickel source is nickel sulfate. It is contemplated that other nickel sources may be used. The amount of nickel is generally from about 2 to 10 g/liter and, more desirably, from about 4 to about 6 g/liter of the aqueous bath solution.

The electroless plating includes from about 88 to 93 wt. % nickel and from at least 7 to about 12 wt. % phosphorous in one embodiment. More specifically, the electroless plating includes from about 88 to about 92 wt. % nickel and from about 8 to about 12 wt. % phosphorous in an another embodiment. The electroless plating includes from about 89 to about 91 wt. % nickel and from about 9 to about 11 wt. % phosphorous in a further embodiment. At these levels, the amount of phosphorous in the nickel-phosphorous plating will assist in reducing the ferromagnetic character of the conductive material. This provides the benefit of producing electrical circuitry with better electrical characteristics such as having a lower order-to-order bandwidth variation than current electrical circuitry created using the current electroless plating. Current electrical circuitry created using current electroless plating has unacceptably high order-to-order bandwidth variation. It is believed to result from the presence of magnetic material from the electroless plating (e.g., nickel-phosphorous plating) is slightly ferromagnetic and that variation in thickness and magnetic character can lead to this effect.

The reducing agent reacts with the metal ions (nickel source) to deposit the metal. In one embodiment, the reducing agent is sodium hypophosphite or hypophosphorous acid. The phosphorous source to be used in the aqueous bath solution is desirably highly soluble in the selected solvent. One example of a salt of hypophosphite is sodium hypophosphite. It is contemplated that other phosphorous sources may be used. It is contemplated that other reducing agents in the aqueous bath solution may be used. The amount of reducing agent is generally from about 20 to about 35 g/liter and, more desirably, from about 25 to about 28 g/liter of the aqueous bath solution.

The pH-controlling material assists in controlling the pH of the aqueous bath solution. Typically, the pH-controlling material increases the pH of the aqueous bath solution. By increasing the pH of the aqueous bath solution, the rate of and content of the phosphate in the electroless plating is controlled. In one embodiment, the pH-controlling material is sodium hydroxide. In another embodiment, the pH-controlling material is potassium hydroxide. It is contemplated that other pH-controlling materials may be used. The pH range of the aqueous bath solution is generally from about 4 to about 5.5 and, more desirably, from about 4.2 to about 4.6. The pH-controlling material is added in a sufficient amount to maintain the aqueous bath solution in its desired pH range.

The stabilizer in the aqueous bath solution assists in preventing or inhibiting extra plating. The stabilizer also assists in preventing or inhibiting spontaneous plating or crashing out when finely divided metal particles are formed in the solution. More specifically, the stabilizer in the aqueous bath solution assists in slowing down the reduction by co-deposition with the nickel. Non-limiting examples of stabilizers that may be used in the aqueous bath solution include lead, antimony, bismuth or combinations thereof. Bismuth is desirable as a stabilizer since it is less toxic than other stabilizers. It is contemplated that other stabilizers may be used in the aqueous bath solutions. The amount of stabilizer is generally from about 200 to about 2,000 ppb and, more desirably, from about 300 to about 1,000 ppb of the aqueous bath solution.

The complexing agent holds onto the nickel source in the aqueous bath solution and assists in releasing the same. The complexing agent increases the phosphite solubility and also slows down the speed of the reaction to assist in preventing or inhibiting the white-out phenomena but are not co-deposited into the resulting alloy. Non-limiting examples of complexing agents that may be used in the aqueous bath solution of according to various embodiments of the present invention include succinic acid, maleic acid, lactic acid, gluconic acid and Krebs-cycle acids. It is contemplated that other complexing agents may be used in the aqueous bath solutions. The amount of complexing agent generally corresponds to the amount of metal in at least a 1:1 molar ratio and more desirably in at least a 3:1 molar ratio, but typically not more than a 4:1 molar ratio.

The conductive material contacts the aqueous bath solution. In one process, the conductive material is immersed into or otherwise contacted with the aqueous bath solution to form the electroless plating. The plating temperature is generally from about 50 to about 95° C. and, more specifically, from about 75 to about 85° C. The aqueous bath solution is generally at a pH of from about 4 to about 5.5 and, more specifically, from about 4.2 to about 4.6.

The thickness of the nickel-phosphorous plating depends on process conditions such as plating dwell time and other variables. It is desirable to have the thickness of the nickel-phosphorous plating at such a level that there is no diffusion from underlying layers (conductive material). One non-limiting example of an underlying layer is a copper layer that can diffuse if the thickness of the nickel-phosphorous plating is too thin. The thickness of the nickel-phosphorous plating is generally from about 50 to about 300 nm. In another embodiment, the thickness of the nickel-phosphorous plating is from about 100 to about 200 nm or, more specifically, from about 125 to about 175 nm.

It is desirable for the thickness of the plating in some embodiments to be greater than 100 nm so as to decrease the porosity and lessen the corrosion risk. Having a thickness of the plating of from about 125 to about 200 nm or, more specifically, from about 125 to about 175 nm, produces good manufacturability (i.e., fast line speed), while still being a thickness that provides robust corrosion protection (i.e., lower porosity).

FIG. 5 is a generally cross-sectional view of the portion of the flexible circuit shown in FIG. 4 after electroless plating nickel and phosphorous on top of the conductive material according to one embodiment. Nickel-phosphorous plating 60 is shown in FIG. 5 on the conductive material (conductive structures 56a, 56b) covers the top and sides of the conductive structures 56a, 56b. The photoresist layer 54 has been removed before the electroless plating occurs.

The electroless plating using the aqueous bath solution of various embodiments of the present invention produces a generally uniform or even deposit of conductive material that extends and includes the edges of, for example, the conductive material (e.g., conductive structures 56a, 56b). The aqueous bath solution desirably may be used for a least 2 to 4 metal turnovers. The aqueous bath solution used in the electroless plating desirably is usable in an in-line, continuous web-production setting and with periodic downtime, while still remaining stable.

After the electroless plating has been completed, it may be left as is without any further processing steps. In another embodiment, after the electroless plating has been completed, the nickel-phosphorous material may be finished with an anti-oxidation or anti-tarnish chemical that is followed by a water treatment. In a further embodiment after the electroless plating has been completed, addition dielectric layer(s) may be added.

The nickel-phosphorous plating is generally uniform with the thickness of the surface is within 20 percent of the average thickness across the surface of the plating. The nickel-phosphorous plating is generally uniform with the thickness of the surface is within 15 percent of the average thickness across the surface of the plating. This uniformity is achieved without requiring an agent in the aqueous bath solution to be added to control the thickness around the edges of the plating.

The general uniformity is achieved at least partly from controlling the fluid mechanics of the process used in the electroless plating. Specifically, avoiding turbulent flow and drawing the article slowly through the bath. For example, a shear velocity in the range of about 2 to about 10 cm/sec and, more preferably, from about 4 to about 6 cm/sec.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

### Examples

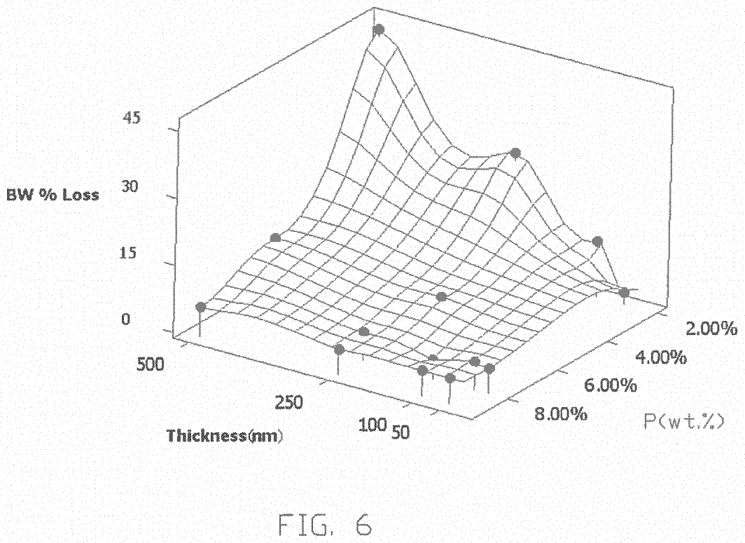

Referring to FIG. 6, the bandwidth loss (%) was plotted on a 3-dimensional graph using the thickness (in nm) of the plating and the percentage (wt. %) of phosphorous in the electroless nickel-phosphorous plating. As shown in FIG. 6, when the phosphorous content was at least 7 wt. % and more desirably 8 wt. % with a thickness of less than about 300 nm, then the bandwidth loss was a lower and desirable number. When the phosphorous content was about 6 wt. % or less, then the bandwidth loss started showing higher bandwidth losses as the thicknesses were increased, which produced undesirable bandwidth losses.

While the invention is amenable to various modifications and alternative forms, specific embodiments or methods have been shown by way of example in the drawings and are described in detail below. The intention, however, is not to limit the invention to the particular embodiments described. On the contrary, the invention is intended to cover all modifications, equivalents, and alternatives falling within the scope of the invention as defined by the appended claims.

We claim:

1. A method of forming material for a circuit, the method comprising:
forming a substrate;
forming a dielectric polymer layer;
forming a seed layer in which the dielectric polymer layer is located between the substrate and the seed layer;
placing conductive material on a first portion of the seed layer;
contacting the conductive material with or in an aqueous bath solution; and
electroless plating on top of the conductive material, the electroless plating including the aqueous bath solution comprised of at least one solvent, a nickel source, a phosphorous source, a reducing agent, a pH-controlling material, a stabilizer and a complexing agent;
wherein the plating includes from about 88 to 93 wt. % nickel and from at least 7 to about 12 wt. % phosphorous to form a nickel-phosphorous plating on the conductive material,
wherein the thickness of the nickel-phosphorous plating is from about 50 to about 300 nm,
wherein the nickel-phosphorous plating is generally uniform with the thickness of the surface being within 20 percent of the average thickness across the surface of the plating.

2. The method of claim 1, wherein the nickel source is nickel sulfate.

3. The method of claim 1, wherein the reducing agent is sodium hypophosphite or hypophosphorous acid.

4. The method of claim 1, wherein the pH-controlling material is sodium hydroxide or potassium hydroxide.

5. The method of claim 1, wherein the stabilizer is bismuth.

6. The method of claim 1, wherein the complexing agent is succinic acid, maleic acid, lactic acid, gluconic acid or a Krebs-cycle acid.

7. The method of claim 1, wherein the thickness of the nickel-phosphorous plating is from about 100 to about 200 nm.

8. The method of claim 7, wherein the thickness of the nickel-phosphorous plating is from about 125 to about 175 nm.

9. The method of claim 1, wherein the conductive material is copper or a copper alloy.

10. The method of claim 1, wherein the plating includes from about 88 to about 92 wt. % nickel and from about 8 to about 12 wt. % phosphorous.

11. The method of claim 10, wherein the plating includes from about 89 to about 91 wt. % nickel and from about 9 to about 11 wt. % phosphorous.

12. The method of claim 1, wherein the at least one solvent is water.

13. The method of claim 1, wherein the nickel-phosphorous plating is generally uniform with the thickness of the surface being within 15 percent of the average thickness across the surface of the plating.

14. A method of forming material for a circuit, the method comprising:
forming a substrate;
forming a dielectric polymer layer;
forming a seed layer in which the dielectric polymer layer is located between the substrate and the seed layer;
placing conductive material on a first portion of the seed layer, the conductive material being copper or a copper alloy;
contacting the conductive material with or in an aqueous bath solution; and
electroless plating on top of the conductive material, the electroless plating including the aqueous bath solution consisting essentially of at least one solvent, a nickel source, a phosphorous source, a reducing agent, a pH-controlling material, a stabilizer and a complexing agent, the reducing agent being sodium hypophosphite or hypophosphorous acid, the pH-controlling material being sodium hydroxide or potassium hydroxide, and the complexing agent being succinic acid, maleic acid, lactic acid, gluconic acid or a Krebs-cycle acid,
wherein the plating includes from about 88 to about 92 wt. % nickel and from about 8 to about 12 wt. % phosphorous to form a nickel-phosphorous plating on the conductive material,
wherein the thickness of the nickel-phosphorous plating is from about 100 to about 300 nm,
wherein the nickel-phosphorous plating is generally uniform with the thickness of the surface is within 20 percent of the average thickness across the surface of the plating.

15. The method of claim 14, wherein the thickness of the nickel-phosphorous plating is from about 125 to about 175 nm.

16. The method of claim 14, wherein the conductive material is copper or a copper alloy.

17. The method of claim 14, wherein the plating includes from about 89 to about 91 wt. % nickel and from about 9 to about 11 wt. % phosphorous.

18. The method of claim 14, wherein the at least one solvent is water.

19. The method of claim 14, wherein the nickel-phosphorous plating is generally uniform with the thickness of the surface being within 15 percent of the average thickness across the surface of the plating.

20. A method of plating on top of a conductive material, the method comprising:
providing the conductive material;
providing an aqueous bath solution comprised of at least one solvent, a nickel source, a phosphorous source, a reducing agent, a pH-controlling material, a stabilizer and a complexing agent;
contacting the conductive material with or in the aqueous bath solution; and
electroless plating on top of the conductive material, the plating includes from about 88 to 93 wt. % nickel and from at least 7 to about 12 wt. % phosphorous to form a nickel-phosphorous plating on the conductive material,
wherein the thickness of the nickel-phosphorous plating is from about 50 to about 300 nm,
wherein the nickel-phosphorous plating is generally uniform with the thickness of the surface being within 20 percent of the average thickness across the surface of the plating.

21. The method of claim 20, wherein the reducing agent is sodium hypophosphite or hypophosphorous acid.

22. The method of claim 20, wherein the pH-controlling material is sodium hydroxide or potassium hydroxide.

23. The method of claim 20, wherein the complexing agent is succinic acid, maleic acid, lactic acid, gluconic acid or a Krebs-cycle acid.

24. The method of claim 20, wherein the reducing agent is sodium hypophosphite or hypophosphorous acid, wherein the pH-controlling material is sodium hydroxide or potassium hydroxide and wherein the complexing agent is succinic acid, maleic acid, lactic acid, gluconic acid or a Krebs-cycle acid.

25. The method of claim 20, wherein the thickness of the nickel-phosphorous plating is from about 100 to about 200 nm.

26. The method of claim 25, wherein the thickness of the nickel-phosphorous plating is from about 125 to about 175 nm.

27. The method of claim 25, wherein the plating includes from about 88 to about 92 wt. % nickel and from about 8 to about 12 wt. % phosphorous.

28. The method of claim 27, wherein the plating includes from about 89 to about 91 wt. % nickel and from about 9 to about 11 wt. % phosphorous.
